(19) United States
(12) Patent Application Publication
(10) Pub. No.: US 2012/0145080 A1
(43) Pub. Date: Jun. 14, 2012

(54) SUBSTRATE SUPPORT UNIT, AND APPARATUS AND METHOD FOR DEPOSITING THIN LAYER USING THE SAME

(76) Inventors: YOUNGKYOU PARK, Hwasung-city (KR); Jeongsoo Suh, Hwasung-city (KR); Wangoo Hwang, Hwasung-city (KR); Hoonsang Choi, Hwasung-city (KR); Jongrok Park, Hwasung-city (KR)

(21) Appl. No.: 13/323,214

(22) Filed: Dec. 12, 2011

(30) Foreign Application Priority Data
Dec. 13, 2010 (KR) 10-2010-0127156

(51) Int. Cl. C23C 16/458; C23C 16/46; B23Q 1/64; C23C 16/455

(52) U.S. Cl. 118/725; 118/730; 269/57

(57) ABSTRACT

A substrate support unit includes a support member configured to accommodate a plurality of substrate holders and a driving member configured to rotate the substrate holders and the support member on their respective axes.

### CROSS-REFERENCE TO RELATED APPLICATIONS

This application claims priority under 35 USC §119 to Korean Patent Application No. 10-2010-0127156, filed on Dec. 13, 2010, the disclosure of which is hereby incorporated by reference herein in it's entirety.

### BACKGROUND OF THE INVENTION

Exemplary embodiments of the inventive concept described herein generally relates to substrate support units and apparatuses and methods for depositing a thin film using the same and, more particularly, to a substrate support unit configured to support a plurality of substrates and an apparatus and a method for depositing a thin film on the substrates using the same.

In general, semiconductor devices are manufactured through various processes such as, for example, a deposition process, a photolithography process, an etching process, and a cleaning process. Among these processes, the deposition process is performed to form a material layer on a substrate. The deposition process includes, for example, a chemical vapor deposition (CVD) process, an atomic layer deposition (ALD) process, and so forth.

### SUMMARY OF THE INVENTION

Exemplary embodiments of the inventive concept provide a substrate support unit, and an apparatus and a method for depositing a thin film.

According to an exemplary embodiment of the inventive concept, the substrate support unit may include a support member configured to accommodate a plurality of substrate holders and a driving member configured to rotate the substrate holders and the support member on their respective axes.

According to an exemplary embodiment of the inventive concept, the apparatus for depositing a thin film may include a process chamber, a substrate support unit disposed inside the process chamber and configured to support a plurality of substrates on which a deposition process is being performed and a gas injection unit disposed over the substrate support unit to face the substrates and configured to inject a process gas to the substrates. The substrate support unit may include a support member having an upper surface edge region in which a plurality of substrate holders on which the substrates are placed are disposed in a circumferential direction and a driving member configured to rotate the substrate holders on their respective axes while revolving the substrate holders around an axis of the support member.

According to an exemplary embodiment of the inventive concept, the method for depositing a thin film may include loading a plurality of substrates in an upper surface edge region of a support member in a circumferential direction, heating the substrates and injecting a process gas to upper surfaces of the substrates. The substrates may revolve around an axis of the support member while rotating on their respective axes.

According to an exemplary embodiment of the inventive concept, the apparatus for depositing a thin film may include a process chamber having an upper wall, a sidewall extending downwardly from an edge of the upper wall and a lower wall connected to a bottom end of the sidewall, and a substrate support unit disposed inside the process chamber and configured to support a plurality of substrates on which a deposition process is being performed. The substrate support unit includes a support member which includes an upper rotation plate having a plurality of grooves having a step shape formed in an upper surface edge region thereof, in which the grooves are configured to accommodate a plurality of substrate holders on which the substrates are placed therein and lower surfaces of the substrate holders accommodated within the grooves are provided to have step shapes corresponding to the grooves, a lower rotation plate disposed below the upper rotation plate and a side plate connecting an edge of the upper rotational plate to an edge of the lower rotation plate, a driving member configured to rotate the substrate holders on their respective axes while revolving the substrate holders around an axis of the support member, a gas injection unit disposed over the substrate support unit to face the substrates, and a gas supply pipe connected to the gas injection unit through the upper wall of the process chamber to inject a process gas to the substrates.

The apparatus depositing a thin film may further include a blocking plate configured to prevent reactive byproducts and residual gases from flowing into the substrate support unit, and in which the blocking plate is disposed within the process chamber between the sidewall of the process chamber and the substrate support unit, thereby defining a space between the blocking plate and the sidewall of the process chamber, and an exhaust unit operatively connected to an exhaust hole formed in an area of the lower wall of the process chamber which corresponds to the space between the blocking plate and the sidewall of the process chamber. The exhaust unit is configured to exhaust the reactive byproducts and the residual gas flowing in the space between the blocking plate and the sidewall of the process chamber out of the process chamber through the exhaust hole.

### BRIEF DESCRIPTION OF THE DRAWINGS

Exemplary embodiments of the inventive concept can be understood in more detail in view of the attached drawings and accompanying detailed description. Exemplary embodiments depicted therein are provided by way of example, not by way of limitation, wherein like reference numerals refer to the same or similar elements. The drawings are not necessarily to scale, emphasis instead being placed upon illustrating exemplary embodiments of the inventive concept.

FIG. 1 is a cross-sectional view of an apparatus for depositing a thin film according to an exemplary embodiment of the inventive concept.

FIG. 2 is a perspective view of a substrate support unit shown in FIG. 1.

FIG. 3 is a cross-sectional view of the substrate support unit shown in FIG. 1.

FIG. 4 is a perspective view of a lower rotation plate and first and second gears shown in FIG. 3.

FIGS. 5A and 5B is a partial cross-sectional view of a substrate holder and an upper rotation plate shown in FIG. 3

FIG. 6 is a top plan view of a substrate support unit according to an exemplary embodiment of the inventive concept.

FIG. 7 is a cross-sectional view of a substrate support unit according to an exemplary embodiment of the inventive concept.

FIG. 8 is a top plan view of the substrate support unit shown in FIG. 7.

FIG. 9 is a cross-sectional view of an apparatus for depositing a thin film according to an exemplary embodiment of the inventive concept.

### DETAILED DESCRIPTION

Exemplary embodiments of the inventive concept will now be described more fully hereinafter with reference to the accompanying drawings. However, exemplary embodiments of the inventive concept may be embodied in many different forms and should not be construed as limited to exemplary embodiments set forth herein. Like numbers refer to like elements throughout.

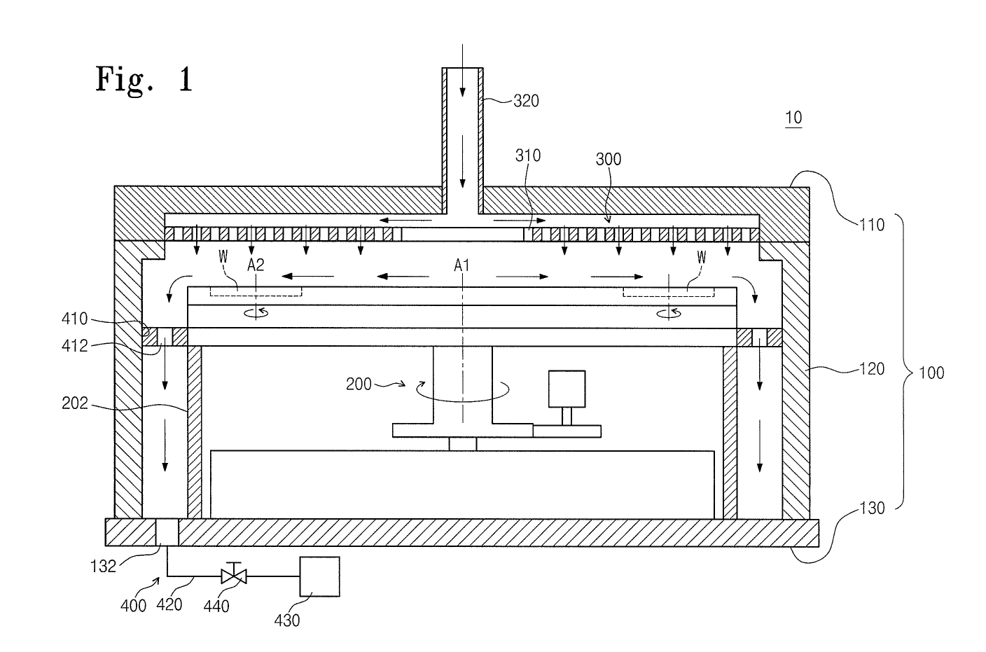

FIG. 1 is a cross-sectional view of an apparatus 10 for depositing a thin film according to an exemplary embodiment of the inventive concept. As illustrated, the apparatus 10 includes, for example, a process chamber 100, a substrate support unit 200, a gas injection unit 300, and an exhaust unit 400. The apparatus 10 may deposit a thin film on a substrate W by means of, for example, chemical vapor deposition (CVD) or atomic layer deposition (ALD). A substrate W used in a thin film deposition process may be, for example, a silicon wafer for use in manufacturing of a semiconductor integrated circuit (IC).

The process chamber 100 provides a space in which a thin film deposition process is performed. The process chamber 100 has, for example, an upper wall 110, a sidewall 120 extending downwardly from the edge of the upper wall 110, and a lower wall 130 connected to the bottom end of the sidewall 120. The upper wall 110 and the lower wall 130 may each be provided to have, for example, a disc shape. A path (not shown) may be provided at the sidewall 120 of the process chamber 100. A substrate W is taken in or out along the path.

The substrate support unit 200 is disposed inside the process chamber 100 and supports a plurality of substrates W to make their processed surface face up. The substrates W are arranged at an upper surface edge region of a support member (not shown and described later) in a circumferential direction. The substrate support unit 200 may rotate the respective substrates W on its axis A2 while revolving the substrates W around an axis A1 of the support member (not shown and described later). That is, the substrate support unit 200 may rotate and revolve the substrates W at the same time. Elements associated with rotation and revolution of a substrate W will be described in detail later. Inside the substrate support unit 200, a heating member (not shown) may be disposed to heat the substrates W at a process temperature. For example, at the circumference of the substrate support unit 200, a blocking plate 202 may be provided to prevent reactive byproducts and residual gases from flowing into the substrate support unit 200. The reactive byproducts and the residual gases are exhausted to the outside of the process chamber 100 through a space formed between the blocking plate 202 and the sidewall 120 of the process chamber 100.

The gas injection unit 300 is provided over the substrate support unit 200 at an inner side of the process chamber 100 to face the substrates W and injects a process gas to the substrates W. The gas injection unit 300 may be, for example, referred to as a shower head where a plurality of injection holes 310 are formed to inject the process gas. The injection holes 310 may be formed, for example, radially on the basis of a central region of the gas injection unit 300. A gas supply pipe 320 is in fluid communication with the gas injection unit 300 to supply the process gas, and the gas supply pipe 320 is connected to the gas unit injection unit 300 through the upper wall 110 of the process chamber 100.

The exhaust unit 400 exhausts the reactive byproducts and the residual gas inside the process chamber 100 to the outside. The exhaust unit 400 includes, for example, an exhaust plate 410, an exhaust line 420, an exhaust member 430, and a valve 440. The exhaust plate 410 is provided to have, for example, a ring shape. The exhaust plate 410 may be disposed such that its outer circumferential surface is in contact with the sidewall 120 of the process chamber 100 and its inner circumferential surface is in contact with an outer circumferential surface of the support member of the substrate support unit 200. A plurality of holes 412 are formed at the exhaust plate 410 in a circumferential direction. An exhaust hole 132 is formed in a region of the lower wall 130 of the process chamber 100 which corresponds to a space between the blocking plate 202 and the sidewall 120 of the process chamber 100. One end of the exhaust line 420 is connected to the exhaust hole 132 and the other end thereof is connected to the exhaust member 430. The valve 440 is disposed on the exhaust line 420 to open and close the flow of the reactive byproducts and the residual gases via an internal space of the exhaust line 420. When the exhaust member 430 applies a negative pressure into the process chamber 100, unwanted reactive byproducts and residual gases inside the process chamber 100 are exhausted to the outside of the process chamber 100 through the exhaust hole 132 after flowing into the space between the blocking plate 202 and the sidewall 120 of the process chamber 100 through the holes 412 of the exhaust plate 410.

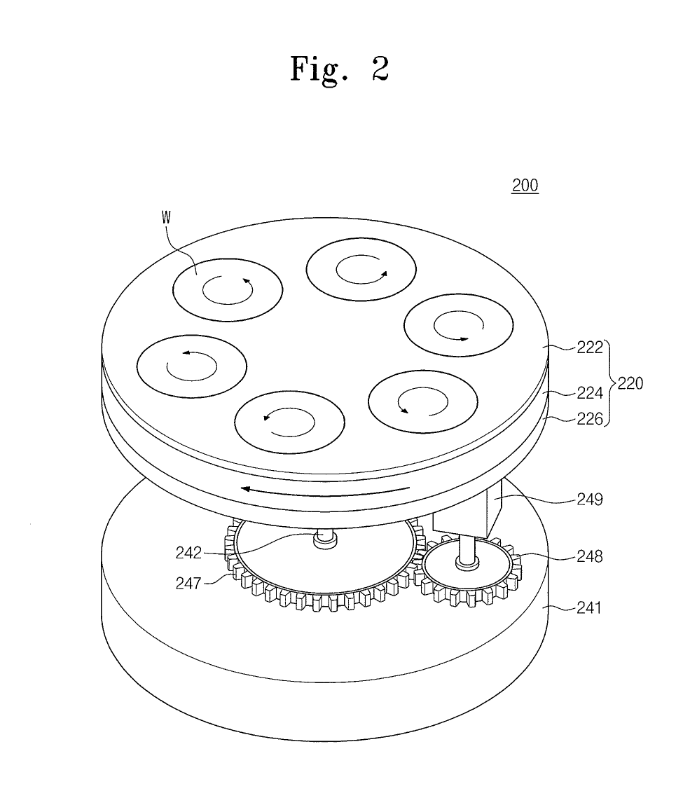

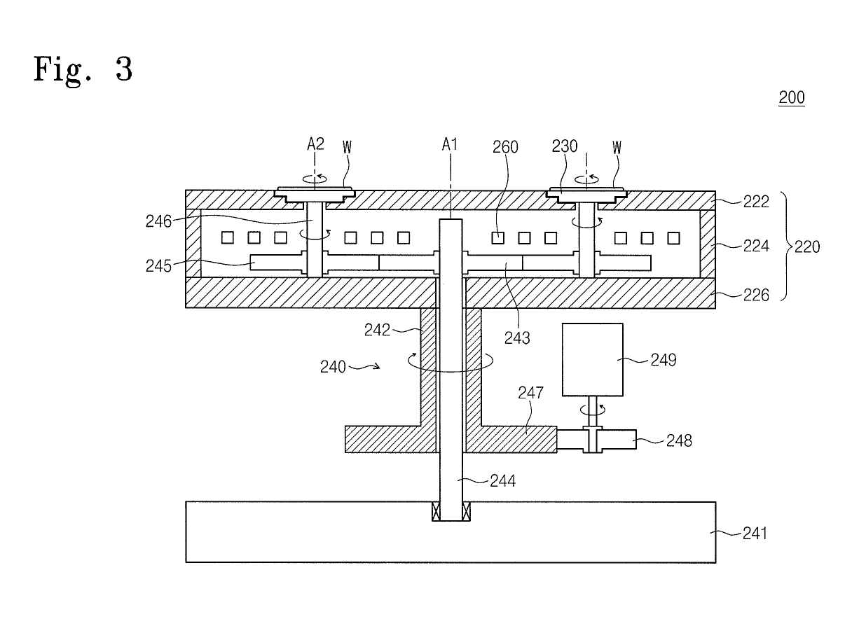

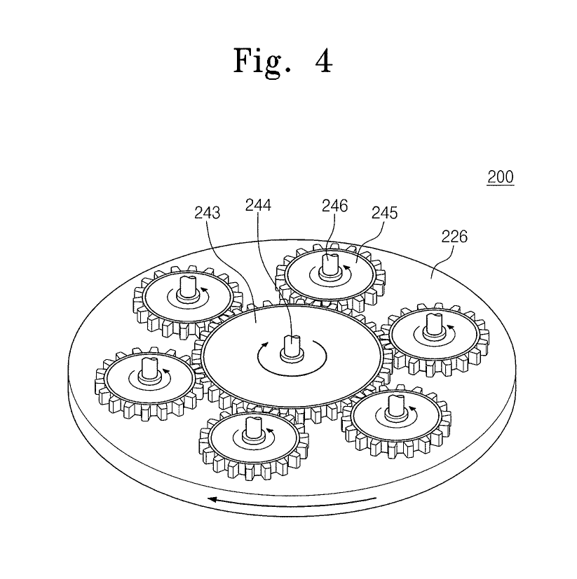

FIGS. 2 and 3 are a perspective view and a cross-sectional view of the substrate support unit 200 shown in FIG. 1, respectively. FIG. 4 is a perspective view of a lower rotation plate and first and second gears shown in FIG. 3. Referring to FIGS. 2 to 4, the substrate support unit 200 includes, for example, a support member 220, a driving member 240, and a heating member 260.

The support member 220 accommodates a plurality of substrate holders 230 on which substrates W are placed. The substrate holder 230 is referred to as a pocket by a person of ordinary skill in the art. The support member 220 includes, for example, an upper rotation plate 222 where the substrate holders 230 are disposed, a lower rotation plate 224 disposed below the upper rotation plate 222, and a side plate 226 connecting the edge of the upper rotation plate 222 to the edge of the lower rotation plate 224.

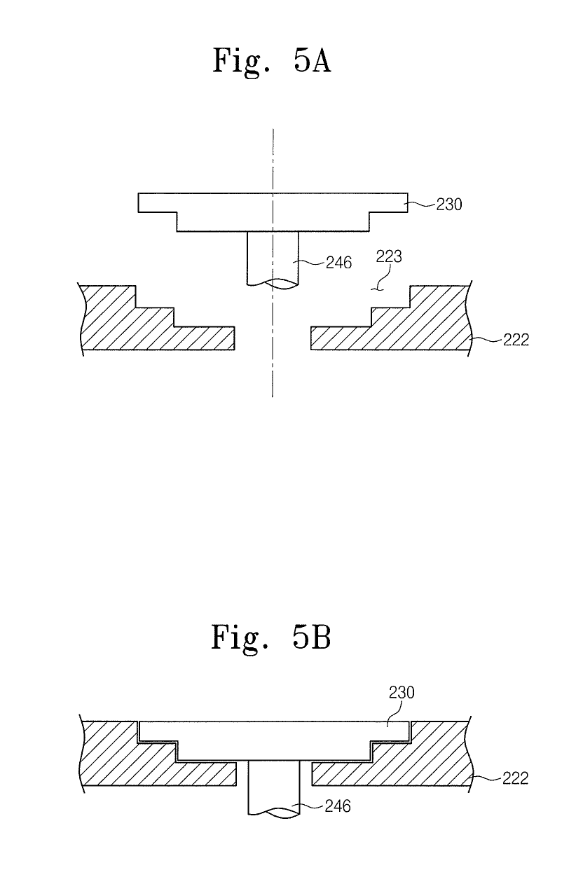

A plurality of substrate holders 230 are disposed in an upper surface edge region of the upper rotation plate 222 in a circumferential direction. As shown in FIGS. 5A and 5B, a plurality of grooves 223 are formed in the upper edge region of the upper plate 222 in the circumferential direction. The substrate holders 230 are accommodated within the grooves 223, respectively. Further, as shown in FIGS. 5A and 5B, the groove 223 may be formed to have, for example, a step shape, e.g., an open area of the groove 223 may decrease as it goes downwardly. A bottom surface of the substrate holder 230 may be provided to have, for example, a step shape corresponding to the groove 223. If bottom surfaces of the grooves 223 and the substrate holders 230 each have a step shape, particles may be prevented from flowing into the support member 220 through spaces between the grooves 223 of the upper rotation plate 222 and the substrate holders 230 to prevent the particles from contaminating the driving member 240 inside the support member 220.

The driving member 240 rotates the support member 220 on its first axis A1 to revolve the substrate holders 230 around the first axis A1 while rotating the substrate holders 230 on its second axis A2. Accordingly, the substrates W revolve around its first axis A1 of the support member 220 while rotating on its second axis A2.

The driving member 240 includes, for example, a base 241, a driving shaft 242, a first rotation shaft 244, second rotation shafts 246, a driven gear 247, a driving gear 248, and a rotation driver 249. The driving shaft 242 is provided in the form of, for example, a hollow shaft and is perpendicularly connected to a bottom surface central portion of the lower rotation plate 226. A first rotation shaft 244 is inserted into the driving shaft 242 to be rotatable independently of the driving shaft 242. The first rotation shaft 244 is inserted into the driving shaft 242 such that the upper end of the first rotation shaft 244 is disposed in an inner space of the support member 220 formed by the upper rotation plate 222, the side plate 224, and the lower plate 226. The lower end of the first rotation shaft 244 is rotatably coupled to the base 241. A first gear 243 is horizontally rotatably coupled to the upper end of the first rotation shaft 244 disposed between the upper rotation plate 222 and the lower rotation plate 226. The second rotation shafts 246 are provided inside the support member 220 in a number corresponding to the number of the substrate holders 230. The upper end of each of the second rotation shafts 246 is coupled to a bottom surface central portion of the substrate holder 230 through the upper rotation plate 222, and the lower end thereof is rotatably coupled to the lower rotation plate 226. The second gear 245 engaging with the first gear 243 is coupled to the lower end of the second rotation shaft 246. The driven gear 247 is horizontally coupled to the lower end of the driving shaft 242. The driving gear 248 is horizontally disposed to engage with the driven gear 247 and rotated by the rotation driver 249 such as, for example, a motor.

The heating member 260 is disposed between the upper rotation plate 222 and the first and second gears 243 and 245 and heats substrates W placed on the substrate holders 230 at a process temperature. For example, the heating member 260 may be provided as a narrow and long plate and provided to coplanarly have a spirally winding shape.

If substrates W are loaded on the substrate holders 230 respectively, the substrates W revolve due to rotation of the support member 220 on its first axis A1 and rotate due to the rotation of the substrate holders 230 on its second axis A2. The rotation of the substrate holders 230 on its second axis A2 is done by receiving a rotational force from the support member 220. This will now be described below in detail.

A rotation driving force of the rotation driver 249 is transferred to the driving shaft 242 through the driving gear 248 and the driven gear 247. The rotation of the driving shaft 242 allows the support member 220 to rotate on its first axis A1. At this point, the second rotation shafts 246 coupled to the support member 220, the substrate holders 230 coupled to the upper end of the second rotation shafts 246, and the second gears 245 coupled to the lower end of the second rotation shafts 246 revolve around their first axis A1 due to the rotation of the support member 220. The revolution of the second gears 245 allows the first gear 243 engaging with the second gears 245 to rotate on its first axis A1, and the rotation of the first gear 243 allows the second gears 245 to rotate on its second axis A2, respectively.

Due to the above-described operations of the driving member 240, during the revolution and rotation of the substrates W, the heating member 260 heats the substrates W placed on the substrate holders 230 at a process temperature and the gas injection unit (300 in FIG. 1) injects a process gas to substrates. The process gas injected to substrates heated at the process temperature is decomposed on a substrate and a film is deposited on the substrate by deposited gas components.

When a substrate only revolves around its first axis A1, the process gas injected by the gas injection unit 300 flows in a radius direction (R direction). Therefore, the thickness and composition of a film may be uniform in a rotation direction (0 direction) but may not be uniform in the radius direction (R direction). However, when a substrate revolves around its first axis A1 while rotating on its second axis A2, a film having a uniform thickness and composition in both the rotation direction (θ direction) and the radius direction (R direction) may be obtained.

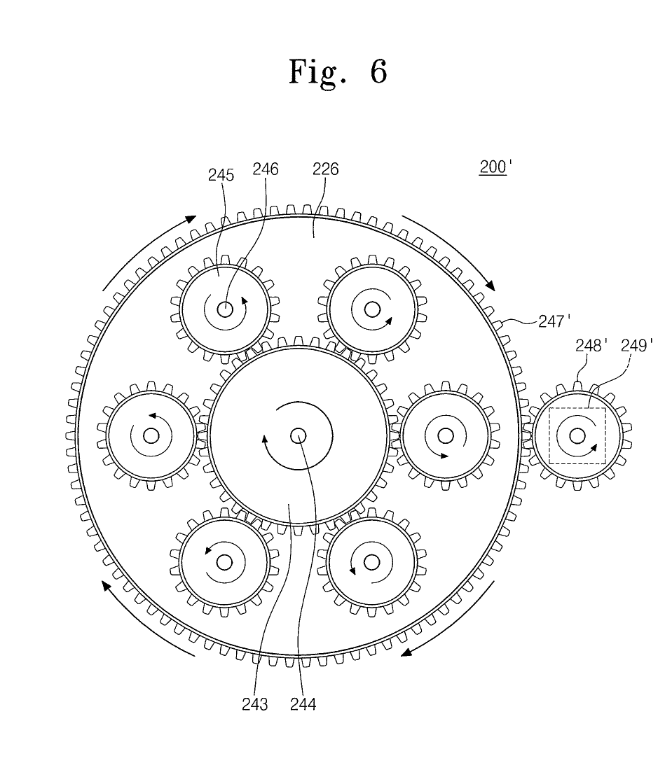

FIG. 6 is a top plan view of a substrate support unit 200′ according to an exemplary embodiment of the inventive concept.

Referring to FIG. 6, except for a driven gear 247′, a driving gear 248′, and a rotation driver 249′, the configuration of the substrate support unit 200′ may be identical to that of the substrate support unit 200 illustrated in FIGS. 2 to 4. Therefore, only the above different elements will now be described.

The driven gear 247′ may be provided at an exterior circumferential surface of a lower rotation plate 226. Alternatively, the driven gear 247′ may be provided at an exterior circumferential surface of an upper rotation plate 226 or an exterior circumferential surface of a side plate 224. The driving gear 248′ may be horizontally disposed to engage with the driven gear 247′ and may be rotated by the rotation driver 249′ such as, for example, a motor.

A rotation driving force of the rotation driver 249′ is transferred to the lower rotation plate 226 through the driving gear 248′ and the driven gear 247′. The rotation of the lower rotation plate 226 allows second rotation shafts 246 coupled to the lower rotation plate 226, substrate holders 230 coupled to the upper end of the second rotation shafts 226, and second gears 245 coupled to the lower end of the second rotation shafts 246 to revolve around their first axis A1. The revolution of the second gears 245 allows a first gear 243 engaging with the second gears 245 to rotate on its first axis A1, and the rotation of the first gear 243 allows the second gears 245 to rotate on its second axis A2. Due to the above operation, substrates W placed on the substrate holders 230 may revolve and rotate.

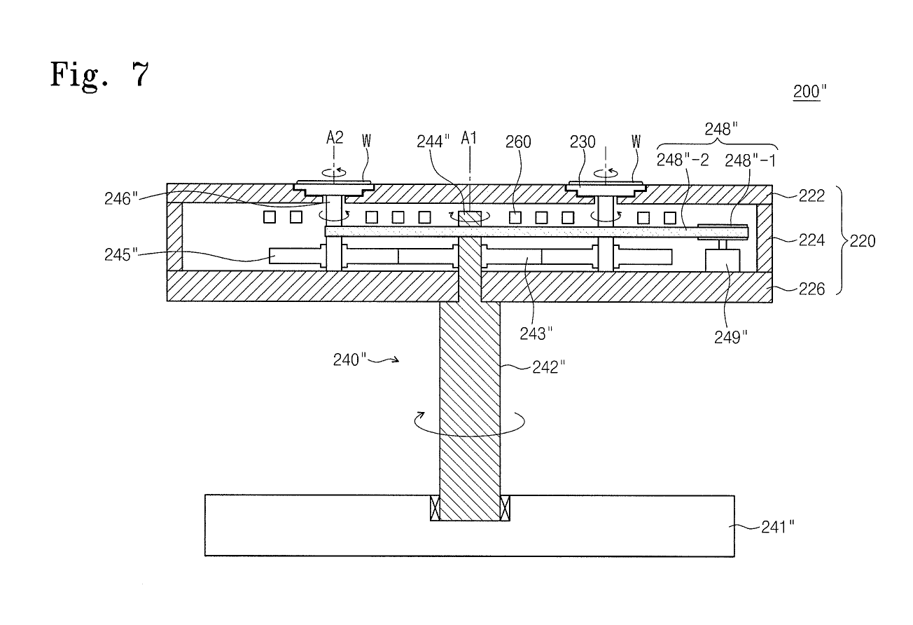

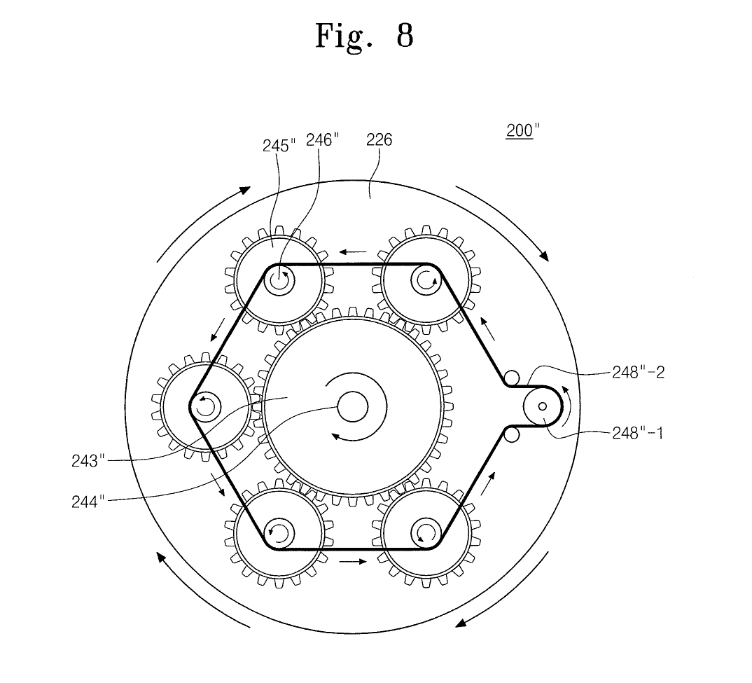

FIG. 7 is a cross-sectional view of a substrate support unit 200″ according to an exemplary embodiment of the inventive concept, and FIG. 8 is a top plan view of the substrate support unit shown in FIG. 7.

Referring to FIGS. 7 and 8, except for a driving member 240″, the configuration of the substrate support unit 200″ may be identical to that of the substrate support unit 200 illustrated in FIGS. 2 to 4. Therefore, only the above different elements will now be described.

The driving member 240″ rotates substrate holders 230 on its second axis A2 while rotating a support member 220 on its first axis A1 to revolve the substrate holders 230 around its first axis A1. Accordingly, substrates W each rotate on its second axis A2 while revolving around its first axis A1 of the support member 220.

The driving member 240″ includes, for example, a base 241″, a driving shaft 242″, a first rotation shaft 244″, second rotation shafts 246″, a belt-pulley assembly 248″, and a rotation driver 249″. The driving shaft 242″ is perpendicularly coupled to a lower surface central portion of a lower rotation plate 226, and the lower end of the driving shaft 242″ is rotatably coupled to the base 241″. The first rotation shaft 244″ is provided between an upper rotation plate 222 and the lower rotation plate 226 and is axially coupled to the driving shaft 242″. A first gear 243″ is horizontally rotatably coupled to the first rotation shaft 244″. The second rotation shafts 246″ are provided inside a support member 220 in a number corresponding to the number of the substrate holders 230. The upper end of each of the second rotation shafts 246″ is coupled to a lower surface central portion of the substrate holder 230 through the upper rotation plate 222, and the lower end of each of the second rotation shafts 246″ is rotatably coupled to the lower rotation plate 226. A second gear 245″ engaging with the first gear 243″ is coupled to the lower end of the second rotation shaft 246″. The rotation driver 249″, such as, for example, a motor, is disposed at one side on the lower rotation plate 226. The belt-pulley assembly 248″ transfers a rotational force from the rotation driver 249″ to the second rotation shafts 246″. The belt-pulley assembly 248″ includes, for example, a driving pulley 248″-1 and a belt 248″-2. The driving pulley 248″-1 is connected to the rotation driver 249″, and the belt 248″-2 is wound on the driving pulley 248″-1 and the second rotation shafts 246″. A circumferential surface of the second rotation shafts 246″ and a contact surface of the belt 248″-1 contacting the second rotation shafts 246″ may each have, for example, an uneven ( [symbol] ) shape to increase friction resistance.

If substrates W are loaded on the substrate holders 230 respectively, the substrates W rotate due to rotation of the respective substrate holders 230 on its second axis A2 and revolve due to the revolution of the substrate holders 230 on its first axis A1. The revolution of the substrate holders on its first axis A1 is done by receiving a rotational force from the support member 220. This will now be described below in detail.

A rotation driving force of the rotation driver 249″ is transferred to the second rotation shafts 246″ by the belt-pulley assembly 248″. The rotation of the second rotation shafts 246″ allows the substrate holders 230 and the second gears 245″ to rotate on its second axis A2. The rotation of the substrate holders 230 allows substrates W to rotate around themselves. The rotation of the second gears 245″ allows the first gear 243″ engaging with the second gears 245″ to rotate on its first axis A1, and the rotation of the first gear 243″ allows the first rotation shaft 244″ and the driving shaft 242″ and the support member 220 connected thereto to rotate. The rotation of the support member 220 allows the substrate holders 230 to rotate on its first axis A1, which allows the substrates W to revolve around its first axis A1.

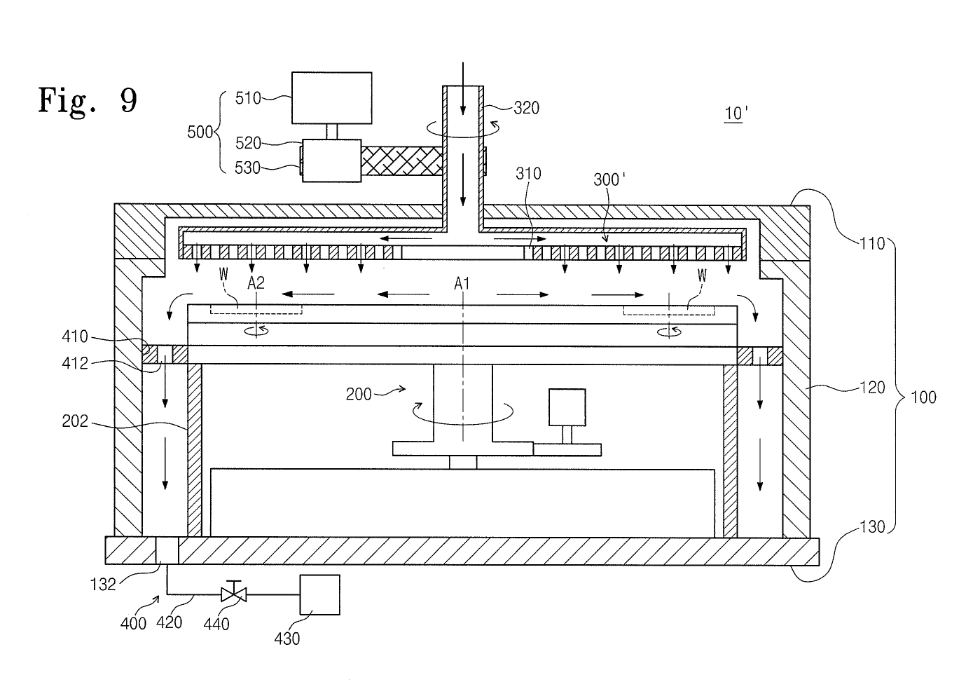

According to the above-described exemplary embodiments, it has been described that a gas injection unit 300 injecting a process gas to substrates W is fixed to an upper portion inside a process chamber 100. However, as shown in an exemplary embodiment of the inventive concept illustrated in FIG. 9, a gas injection unit 300′ may be rotatably provided at an upper portion inside a process chamber 100. Referring to FIG. 9, except for gas injection unit 300′ and rotation driving unit 500, the configuration of the apparatus 10′ for depositing a thin film in FIG. 9 may be identical to that of the apparatus 10 for depositing a thin film illustrated in FIG. 1 Therefore, only the above different elements will now be described. As shown in FIG. 9, the rotation driving unit 500 rotating the gas injection unit 300′ may include, for example, a motor 510, a pulley 520, and a belt 530. The pulley 520 is coupled to a rotation shaft of the motor 510. The belt 530 is wound on the pulley 520 and a gas supply pipe 320 for supplying a process gas to the gas injection unit 300′. The gas injection unit 300′ may rotate by receiving a rotational force from the motor 510 that is generated by the pulley 520 and the belt 530.

Since the rotation of the gas injection unit 300′ allows a process gas to be more uniformly injected to substrates W, the thickness and composition uniformity of a film deposited on each of the substrates W may be increased.

As described above, with exemplary embodiments of the inventive concept, the thickness and composition uniformity of a film deposited on a substrate can be increased. In addition, residual particles between a substrate holder and a support member can be prevented from contaminating a substrate and a driving member. Having described exemplary embodiments of the inventive concept, it is further noted that it is readily apparent to those of reasonable skill in the art that various modifications may be made without departing from the spirit and scope of the invention which is defined by the metes and bounds of the appended claims.

What is claimed is:

1. A substrate support unit comprising:
a support member configured to accommodate a plurality of substrate holders; and
a driving member configured to rotate the substrate holders and the support member on their respective axes.

2. The substrate support unit of claim 1, wherein the driving member comprises:
a rotatable hollow driving shaft coupled to a lower surface of the support member;
a first rotation shaft inserted into the driving shaft and having an upper end disposed at an inner side of the support member, wherein the upper end of the first rotation shaft is coupled to a first gear ; and
a plurality of second rotation shafts provided at an inner side of the support member, wherein each of the second rotation shafts having an upper end to which the substrate holder is coupled and a lower end to which a second gear engaging with the first gear is coupled.

3. The substrate support unit of claim 2, wherein the driving member further comprises:
a driven gear coupled to a lower end of the driving shaft;
a driving gear engaging with the driven gear; and
a rotation driver configured to rotate the driving gear.

4. The substrate support unit of claim 2, wherein the driving member further comprises:
a driven gear provided at an exterior circumferential surface of the support member;
a driving gear engaging with the driven gear; and
a rotation driver configured to rotate the driving gear.

5. The substrate support unit of claim 2, further comprising:
a heating member disposed between the substrate holders and the first and second gears and configured to heat the substrates placed on the substrate holders.

6. The substrate support unit of claim 1, wherein the driving member comprises:
a rotatable driving shaft coupled to a lower surface of the support member;
a first rotation shaft provided at an inner side of the support member, wherein the first rotation shaft is axially connected to the driving shaft and connected to a first gear ;
a plurality of second rotation shafts provided at an inner side of the support member, wherein each of the second rotation shafts having an upper end coupled to the substrate holder and a lower end coupled to a second gear engaging with the first gear ;
a belt-pulley assembly including a driving pulley and a belt wound on the driving pulley and the second rotation shafts; and
a rotation driver configured to provide a rotational force to the driving pulley.

7. The substrate support unit of claim 1, wherein step-shaped grooves are formed on an upper surface of the support member and the substrate holder is accommodated within the step-shaped grooves, and
wherein lower surfaces of the substrate holders have step shapes corresponding to the step-shaped grooves.

8. An apparatus for depositing a thin film, comprising:
a process chamber;
a substrate support unit disposed inside the process chamber and configured to support a plurality of substrates on which a deposition process is being performed; and
a gas injection unit disposed over the substrate support unit to face the substrates and configured to inject a process gas to the substrates,
wherein the substrate support unit comprises:
a support member having an upper surface edge region in which a plurality of substrate holders on which the substrates are placed are disposed in a circumferential direction; and
a driving member configured to rotate the substrate holders on their respective axes while revolving the substrate holders around an axis of the support member.

9. The apparatus of claim 8, wherein the support member comprises:
an upper rotation plate located where the substrate holders are disposed;
a lower rotation plate disposed below the upper rotation plate; and
a side plate connecting an edge of the upper rotation plate to an edge of the lower rotation plate, and
wherein the driving member comprises:
a rotatable hollow driving shaft coupled to a lower surface central portion of the lower rotation plate;
a first rotation shaft inserted into the driving shaft and having an upper end disposed between the upper rotation plate and the lower rotation plate, wherein the upper end of the first rotation shaft is coupled with a first gear; and
a plurality of second rotation shafts coupled to a lower surface central portion of the substrate holders through the upper rotation plate, wherein each of the second rotation shafts having a lower end rotatably connected to the lower rotation plate and coupled with a second gear engaging with the first gear.

10. The apparatus of claim 9, wherein the driving member comprises:
a driven gear coupled to a lower end of the driving shaft;
a driving gear engaging with the driven gear; and
a rotation driver configured to rotate the driving gear.

11. The apparatus of claim 9, wherein the driving member comprises:
a driven gear provided at an exterior circumferential surface of any one of the upper rotation plate, the side plate, and the lower rotation plate;
a driving gear engaging with the driven gear; and
a rotation driver configured to rotate the driving gear.

12. The apparatus of claim 9, wherein the substrate support unit further comprises:
a heating member disposed between the substrate holders and the first and second gears and configured to heat the substrates placed on the substrate holders.

13. The apparatus of claim 8, wherein the support member comprises:
an upper rotation plate located where the substrate holders are disposed;
a lower rotation plate disposed below the upper rotation plate; and
a side plate connecting an edge of the upper rotation plate to an edge of the lower rotation plate, and
wherein the driving member comprises:
a rotatable hollow driving shaft coupled to a lower surface central portion of the lower rotation plate;
a first rotation shaft provided between the upper rotation plate and the lower rotation plate, wherein the first rotation shaft is axially coupled to the driving shaft and connected to a first gear ;
a plurality of second rotation shafts coupled to a lower surface central portion of the substrate holder through the upper rotation plate, wherein each of the second rotation shafts having a lower end rotatably connected to the lower rotation plate and coupled to a second gear engaging with the first gear ;
a belt-pulley assembly including a driving pulley disposed between the upper rotation plate and the lower rotation plate and a belt wound on the driving pulley and the second rotation shafts; and
a rotation driver configured to provide a rotational force to the driving pulley.

14. The apparatus of claim 13, wherein the substrate support unit further comprises:
a heating member disposed between the substrate holders and the first and second gears and configured to heat the substrates placed on the substrate holders.

15. The apparatus of claim 9, wherein a plurality of step-shaped grooves are formed in an upper surface edge region of the upper rotation plate in a circumferential direction and decrease in open area as they go downwardly, and
wherein lower surfaces of the substrate holders accommodated within the grooves are provided to have step shapes corresponding to the grooves.

16. An apparatus for depositing a thin film, comprising:
a process chamber having an upper wall, a sidewall extending downwardly from an edge of the upper wall and a lower wall connected to a bottom end of the sidewall;
a substrate support unit disposed inside the process chamber and configured to support a plurality of substrates on which a deposition process is being performed wherein the substrate support unit comprises:
a support member includes an upper rotation plate having a plurality of grooves having a step shape formed in an upper surface edge region thereof, wherein the grooves are configured to accommodate a plurality of substrate holders on which the substrates are placed therein and lower surfaces of the substrate holders accommodated within the grooves are provided to have step shapes corresponding to the grooves, a lower rotation plate disposed below the upper rotation plate and a side plate connecting an edge of the upper rotational plate to an edge of the lower rotation plate;
a driving member configured to rotate the substrate holders on their respective axes while revolving the substrate holders around an axis of the support member;
a gas injection unit disposed over the substrate support unit to face the substrates;
a gas supply pipe connected to the gas injection unit through the upper wall of the process chamber to inject a process gas to the substrates;
a blocking plate configured to prevent reactive byproducts and residual gases from flowing into the substrate support unit, wherein the blocking plate is disposed within the process chamber between the sidewall of the process chamber and the substrate support unit, thereby defining a space between the blocking plate and the sidewall of the process chamber; and
an exhaust unit operatively connected to an exhaust hole formed in an area of the lower wall of the process chamber which corresponds to the space between the blocking plate and the sidewall of the process chamber, and wherein the exhaust unit is configured to exhaust the reactive byproducts and the residual gas flowing in the space between the blocking plate and the sidewall of the process chamber out of the process chamber through the exhaust hole.

17. The apparatus of claim 16, further comprising a rotation driving unit configured to generate a rotational force to rotate the gas injection unit, wherein the rotation driving unit includes a motor, a pulley coupled to a rotation shaft of the motor and a belt wound on the pulley and the gas supply pipe.

18. The apparatus of claim 16, wherein the exhaust unit comprises:
an exhaust plate having plurality of holes therein and is disposed such that its outer circumferential surface is in contact with the sidewall of the process chamber and its inner circumferential surface is in contact with an outer circumferential surface of the support member of the substrate support unit;
an exhaust member;
an exhaust line having one end connected to the exhaust hole in the lower wall of the process chamber and another end connected to the exhaust member; and
a valve disposed on the exhaust line configured to open and close flow of the reactive byproducts and the residual gases via an internal space of the exhaust line.

19. The apparatus of claim 16, wherein the driving member comprises:
a base;
a driving shaft perpendicularly connected to a bottom surface central portion of the lower rotation plate;
a first rotation shaft inserted into the driving shaft to be rotatable independently of the driving shaft, wherein an upper end of the first rotation shaft is disposed between the upper rotation plate and the lower rotation plate and is horizontally rotatably coupled to a first gear and a lower end of the first rotation shaft is rotatably coupled with the base;
a plurality of second rotation shafts, wherein an upper end of each of the second rotation shafts is coupled to a bottom surface central portion of the substrate holders through the upper rotation plate, and a lower end thereof is rotatably coupled to the lower rotation plate and coupled to a second gear engaging with the first gear;
a driven gear, wherein the driven gear is horizontally coupled to a lower end of the driving shaft;
a driving gear; and
a rotation driver, wherein the driving gear is horizontally disposed to engage with the driven gear and rotated by the rotation driver.

20. The apparatus of claim 16, wherein the driving member comprises:
a rotatable driving shaft perpendicularly coupled to a lower surface central portion of the lower rotation plate and a lower end of the driving shaft is coupled to the base;
a first rotation shaft provided between the upper rotation plate and the lower rotation plate, wherein the first rotation shaft is axially coupled to the driving shaft and connected to a first gear;
a plurality of second rotation shafts coupled to a lower surface central portion of the substrate holder through the upper rotation plate, wherein each of the second rotation shafts having a lower end rotatably connected to the lower rotation plate and coupled to a second gear engaging with the first gear;
a belt-pulley assembly including a driving pulley disposed between the upper rotation plate and the lower rotation plate and a belt wound on the driving pulley and the second rotation shafts; and
a motor disposed at one side of the lower rotation plate and configured to provide a rotational force to the driving pulley.
